(19) United States
(12) Patent Application Publication
(10) Pub. No.: US 2026/0039316 A1
(43) Pub. Date: Feb. 5, 2026

(54) GENERATING AND ORDERING SYMBOLS EMULATING LOWER-ORDER MODULATION SCHEMES IN A HIGHER-ORDER CONSTELLATION

(71) Applicant: Microchip Technology Incorporated, Chandler, AZ (US)

(72) Inventor: Peter Graumann, Calgary (CA)

(21) Appl. No.: 19/353,459

(22) Filed: Oct. 8, 2025

Related U.S. Application Data
(63) Continuation-in-part of application No. 19/070,424, filed on Mar. 4, 2025.
(60) Provisional application No. 63/561,153, filed on Mar. 4, 2024.

(51) Int. Cl. H03M 13/25; H04L 1/00; H04L 27/34

(52) U.S. Cl. CPC H03M 13/25; H04L 1/0003; H04L 27/34

(57) ABSTRACT

A method may include receiving a plurality of input bits; determining, using a convolutional trellis, a state transition of the convolutional trellis at least partially responsive to a first subset of the input bits; selecting, from a symbol alphabet that is a subset of a constellation of signal‑level patterns of a multi-level modulation scheme, a group of symbols pre‑associated with the determined state transition and identified at least partially by a second subset of the input bits; and serializing and transmitting the selected group of symbols.

### CROSS-REFERENCE TO RELATED APPLICATIONS

This application is a continuation-in-part under 35 U.S.C. § 120 of U.S. Patent Application No. 19/070,424, filed on March 4, 2025, which claims the benefit under 35 U.S.C. § 119(e) of U.S. Provisional Patent Application No. 63/561,153, filed on March 4, 2024, the contents and disclosures of which are incorporated herein in their entirety by this reference.

### FIELD

Examples relate generally to high-speed digital communications, and more particularly to trellis-coded modulation utilized to generate and transmit symbols according to multi-level modulation schemes.

### BACKGROUND

In modern high-speed communication systems, multi-level modulation schemes such as Pulse Amplitude Modulation (PAM) are employed to transmit data over channels by mapping digital bits to discrete signal levels in a constellation. These schemes enable higher data rates by utilizing multiple amplitude levels, allowing more information to be conveyed per symbol compared to binary modulation. Trellis-coded modulation (TCM) integrates convolutional coding with modulation, providing error correction capabilities while selecting symbols from subsets of the constellation to increase transmission efficiency.

### BRIEF DESCRIPTION OF THE DRAWINGS

To easily identify the discussion of any particular element or act, the most significant digit or digits in a reference number refer to the figure number in which that element is first introduced.

FIG. 1 is a block diagram depicting an apparatus that generates and orders symbols for transmission in a trellis-coded modulation system in accordance with one or more examples.

FIG. 2 is a block diagram depicting a detailed view of a mapper for selecting symbol signal levels in a trellis-coded modulation system in accordance with one or more examples.

FIG. 3 illustrates an example process for configuring subset-alphabets in a trellis-coded modulation system, in accordance with one or more examples.

FIG. 4 illustrates an example process for partitioning subset-alphabets in a trellis-coded modulation system, in accordance with one or more examples.

FIG. 5 illustrates an example process for evaluating and forming partitions of subset-alphabets in a trellis-coded modulation system, in accordance with one or more examples.

FIG. 6 illustrates an example process for configuring trellis states and look-up tables in a trellis-coded modulation system, in accordance with one or more examples.

FIG. 7 illustrates an example process for encoding and transmitting symbols using a convolutional trellis in a trellis-coded modulation system, in accordance with one or more examples.

FIG. 8 illustrates an example process for detailed symbol generation from partitions in a trellis-coded modulation system, in accordance with one or more examples.

FIG. 9 illustrates an example process for generating and ordering symbols in a multi-level modulation scheme, in accordance with one or more examples.

FIG. 10 illustrates an example process for designating subsets in a trellis-coded modulator, in accordance with one or more examples.

FIG. 11 is a block diagram of circuitry that, in some examples, may be used to implement various functions, operations, acts, processes, or methods disclosed herein.

### DETAILED DESCRIPTION

In the following detailed description, reference is made to the accompanying drawings, which form a part hereof, and in which are shown, by way of illustration, specific examples of embodiments in which the present disclosure may be practiced. These embodiments are described in sufficient detail to enable a person of ordinary skill in the art to practice the present disclosure. However, other embodiments may be utilized, and structural, material, and process changes may be made without departing from the scope of the disclosure.

The illustrations presented herein are not meant to be actual views of any particular method, system, device, or structure, but are merely idealized representations that are employed to describe the embodiments of the present disclosure. The drawings presented herein are not necessarily drawn to scale. Similar structures or components in the various drawings may retain the same or similar numbering for the convenience of the reader; however, the similarity in numbering does not mean that the structures or components are necessarily identical in size, composition, configuration, or any other property.

The following description may include examples to help enable one of ordinary skill in the art to practice the disclosed embodiments. The use of the terms “exemplary,” “by example,” and “for example,” means that the related description is explanatory, and though the scope of the disclosure is intended to encompass the examples and legal equivalents, the use of such terms is not intended to limit the scope of an embodiment or this disclosure to the specified components, steps, features, functions, or the like.

It will be readily understood that the components of the embodiments as generally described herein and illustrated in the drawing could be arranged and designed in a wide variety of different configurations. Thus, the following description of various embodiments is not intended to limit the scope of the present disclosure, but is merely representative of various embodiments. While the various aspects of the embodiments may be presented in drawings, the drawings are not necessarily drawn to scale unless specifically indicated.

Furthermore, specific implementations shown and described are only examples and should not be construed as the only way to implement the present disclosure unless specified otherwise herein. Elements, circuits, and functions may be shown in block diagram form in order not to obscure the present disclosure in unnecessary detail. Conversely, specific implementations shown and described are exemplary only and should not be construed as the only way to implement the present disclosure unless specified otherwise herein. Additionally, block definitions and partitioning of logic between various blocks is exemplary of a specific implementation. It will be readily apparent to one of ordinary skill in the art that the present disclosure may be practiced by numerous other partitioning solutions. For the most part, details concerning timing considerations and the like have been omitted where such details are not necessary to obtain a complete understanding of the present disclosure and are within the abilities of persons of ordinary skill in the relevant art.

Those of ordinary skill in the art would understand that information and signals may be represented using any of a variety of different technologies and techniques. Some drawings may illustrate signals as a single signal for clarity of presentation and description. It will be understood by a person of ordinary skill in the art that the signal may represent a bus of signals, wherein the bus may have a variety of bit widths and the present disclosure may be implemented on any number of data signals including a single data signal.

The various illustrative logical blocks, modules, and circuits described in connection with the embodiments disclosed herein may be implemented or performed with a general purpose processor, a special purpose processor, a Digital Signal Processor (DSP), an Integrated Circuit (IC), an Application Specific Integrated Circuit (ASIC), a Field Programmable Gate Array (FPGA) or other programmable logic device, discrete gate or transistor logic, discrete hardware components, or any combination thereof designed to perform the functions described herein. A general‑purpose processor (may also be referred to herein as a host processor or simply a host) may be a microprocessor, but in the alternative, the processor may be any conventional processor, controller, microcontroller, or state machine. A processor may also be implemented as a combination of computing devices, such as a combination of a DSP and a microprocessor, a plurality of microprocessors, one or more microprocessors in conjunction with a DSP core, or any other such configuration. A general-purpose computer including a processor is considered a special-purpose computer while the general-purpose computer executes computing instructions (e.g., software code) related to embodiments of the present disclosure.

The embodiments may be described in terms of a process that is depicted as a flowchart, a flow diagram, a structure diagram, or a block diagram. Although a flowchart may describe operational acts as a sequential process, many of these acts can be performed in another sequence, in parallel, or substantially concurrently. In addition, the order of the acts may be re-arranged. A process may correspond to a method, a thread, a function, a procedure, a subroutine, a subprogram, without limitation. Furthermore, the methods disclosed herein may be implemented in hardware, software, or both. If implemented in software, the functions may be stored or transmitted as one or more instructions or code on computer-readable media. Computer-readable media includes both computer storage media and communication media including any medium that facilitates transfer of a computer program from one place to another.

Any reference to an element herein using a designation such as “first,” “second,” and so forth does not limit the quantity or order of those elements, unless such limitation is explicitly stated. Rather, these designations may be used herein as a convenient method of distinguishing between two or more elements or instances of an element. Thus, a reference to first and second elements does not mean that only two elements may be employed there or that the first element must precede the second element in some manner. In addition, unless stated otherwise, a set of elements may comprise one or more elements.

As used herein, the term “substantially” in reference to a given parameter, property, or condition means and includes to a degree that one of ordinary skill in the art would understand that the given parameter, property, or condition is met with a small degree of variance, such as, for example, within acceptable manufacturing tolerances. By way of example, depending on the particular parameter, property, or condition that is substantially met, the parameter, property, or condition may be at least 90% met, at least 95% met, or even at least 99% met.

As used herein, any relational term, such as “over,” “under,” “on,” “underlying,” “upper,” “lower,” without limitation, is used for clarity and convenience in understanding the disclosure and accompanying drawings and does not connote or depend on any specific preference, orientation, or order, except where the context clearly indicates otherwise.

In this description the term “coupled,” and derivatives thereof may be used to indicate that two elements co-operate or interact with each other. When an element is described as being “coupled” to another element, then the elements may be in direct physical or electrical contact or there may be intervening elements or layers present. In contrast, when an element is described as being “directly coupled” to another element, then there are no intervening elements or layers present. The term “connected” may be used in this description interchangeably with the term “coupled,” and has the same meaning unless expressly indicated otherwise or the context would indicate otherwise to a person having ordinary skill in the art.

As used herein, the terms “assert,” “de-assert” and derivatives thereof used in reference to a pin, means, respectively, to assert or de-assert a signal associated with the pin (e.g., a signal specifically assigned to the pin or a signal to which the pin is specifically assigned, without limitation).

Trellis-coded modulation (TCM) is a technique that integrates convolutional coding with multi-level modulation to achieve coding gain without expanding bandwidth, by mapping coded bits to symbols from a constellation while ensuring good distance properties between signal points. In TCM, a convolutional encoder generates redundant bits that select subsets of the modulation constellation, and uncoded bits choose specific points within those subsets, allowing the system to transmit more bits per symbol reliably over noisy channels. The trellis diagram represents the state transitions of the encoder over time, where paths through the trellis correspond to possible transmitted sequences, and decoding (e.g., via Viterbi algorithm) finds the most likely path based on received signals.

Multi-level modulation schemes, such as Pulse Amplitude Modulation (PAM), use multiple discrete signal levels to encode more information per symbol, with variants like PAM8 employing 8 levels (e.g., {-7, -5, -3, -1, 1, 3, 5, 7}, without limitation) to achieve higher data rates in high-speed serial-deserializer (SerDes) links. In such systems, subsets of the full constellation can emulate lower-order modulation schemes, such as PAM4 (4 levels) or PAM2 (2 levels), without limitation, by restricting symbols to specific level groups, which provides flexibility in coding and error protection. However, selecting and organizing these subsets must consider channel impairments to maintain performance.

High-speed SerDes channels face significant challenges, including inter-symbol interference (ISI), insertion loss, noise, and crosstalk, often mitigated by decision feedback equalization (DFE) at the receiver, which subtracts the effects of previous symbols from the current one based on past decisions.

Examples disclosed herein utilize emulation of lower-order modulation schemes within higher-order constellations to increase performance in trellis-coded systems. Emulating lower-order modulation schemes (e.g., PAM2 or PAM4, without limitation) within a higher-order constellation (e.g., PAM8, without limitation) allows for enhanced error correction by selecting subsets with larger inter-level distances for better noise immunity, achieves coding gain without increasing bandwidth through redundancy in the expanded signal space, and provides flexibility for adaptive data rates in high-speed channels by mimicking simpler modulations while leveraging the full constellation's capacity.

An issue can arise when the last symbol in a transmitted group influences the DFE tap for the next group; if this symbol has high variability (many possible levels closely spaced), it increases decoder hypotheses, leading to path filtering errors, error propagation, and degraded symbol error rates (SER), especially in noisy environments where small level confusions (e.g., between 5 and 7, without limitation) can cascade. Traditional approaches do not adequately constrain this variability, resulting in suboptimal performance and higher power consumption in complex receivers.

One or more examples disclosed herein partition constellation subsets into groups with differing constraints—such as a first partition with more subsets and smaller inter-level spacing (e.g., for PAM2 emulation) and a second with fewer subsets but larger spacing (e.g., for PAM4)—and use TCM state classes to designate these partitions for symbol generation, ensuring symbols from the more constrained partition are positioned last in transmission. This ordering reduces DFE tap options (e.g., reducing from 8 to 4 viable levels, without limitation), enhances minimum distances for better slicing, and improves overall decoding robustness in high-speed communications, while lookup tables and serializers facilitate efficient implementation. By emulating lower-order schemes within a higher-order constellation and enforcing strategic ordering, these techniques achieve superior error resilience and efficiency without additional bandwidth.

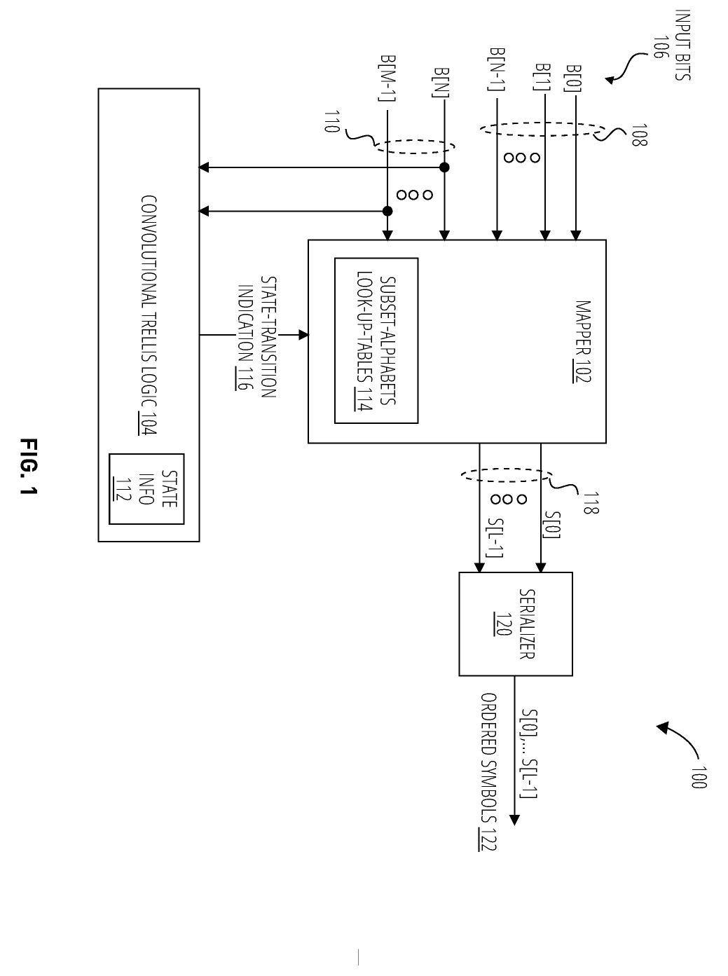

FIG. 1 is a block diagram depicting an apparatus 100 that generates and orders symbols for transmission in a trellis-coded modulation system in accordance with one or more examples. Apparatus 100 may also be referred to as “trellis-coded transmitter 100.”

Generally speaking, the apparatus 100 processes input bits to produce ordered symbols that emulate lower-order multi-level modulation schemes within a higher-order constellation, ensuring that symbols from a more constrained partition are positioned within a transmission sequence after those from a less constrained partition to reduce decision feedback equalization tap variability at a receiver and improve decoding performance, as discussed herein.

The apparatus 100 comprises convolutional trellis logic 104, mapper 102, look-up-tables 114, and serializer 118.

The convolutional trellis logic 104 implements a convolutional encoder integrated with trellis-coded modulation principles, generally used to add redundancy to input data for error correction while mapping to modulation symbols. In one or more examples, the convolutional trellis logic 104 receives input bits 110 and State info 112, determines state transitions based on a subset of the input bits 110, and outputs a state-transition indication 116 that designates subset-alphabets from partitioned subsets of a constellation, such as PAM8 levels {-7, -5, -3, -1, 1, 3, 5, 7}, without limitation, where the designation enforces constraints so that the last symbol in a group is drawn from a partition with larger inter-level spacing, for example at least twice that of the first partition, to reduce the number of viable levels (e.g., from 8 to 4) entering the next trellis state and thereby limit decoder hypotheses.

The mapper 102 translates binary data into signal levels from a modulation constellation, generally handling the selection and output of symbols based on coded inputs. In one or more examples, the mapper 102 receives level-selection bits 108 (which are a subset of the input bits 110) and the state-transition indication 116, accesses subset-alphabets from the look-up-tables 114 to select signal levels that emulate lower-order schemes such as PAM2 or PAM4, without limitation, and outputs a group of symbols S[0] to S[L-1], where L is the group size (e.g., 2 symbols), with S[0] drawn from a less constrained partition (e.g., PAM2 subsets A{7,-1}, B{5,-3}, C{3,-5}, D{1,-7} with smaller spacing, without limitation) and S[L-1] from a more constrained partition (e.g., PAM4 subsets X{7,3,-1,-5}, Y{5,1,-3,-7} with larger spacing of at least 4 units , without limitation), ensuring the symbols collectively encode the input bits 110 while spanning the full constellation.

The look-up-tables 114 are memory structures storing pre-defined associations, generally used for quick retrieval of modulation parameters. In one or more examples, the look-up-tables 114 store subset-alphabets 106, associating identifiers with signal levels evaluated against criteria like minimum Euclidean spacing (e.g., threshold of 4 units for constrained partitions), DC balance (e.g., zero mean over subsets), and average power (e.g., below a threshold to reduce transmission energy), and are accessed by the mapper 102 to generate symbols that restrict the last symbol's options, for instance limiting entry to even states (0-3) to subset X and odd states (4-7) to subset Y in an 8-state trellis, reducing receiver slicing errors by doubling the minimum distance (e.g., from 2 to 4 units).

In one or more examples, the serializer 118 optionally converts parallel data into a serial stream, generally for transmission ordering. In one or more examples, the serializer 118 receives the symbols S[0] to S[L-1] via connection 120 and orders them as ordered symbols 122, positioning the symbol from the more constrained partition last to serve as the decision feedback equalization tap for the next group, thereby minimizing variability (e.g., only 4 levels possible instead of 8) and enhancing performance in channels with inter-symbol interference.

The input bits 110 are divided into groups B[0] to B[M-1], with subsets like B[0] to B[N-1] for trellis selection and B[N] to B[M-1] as level-selection bits 108, enabling the encoding of 3 bits per 2-symbol group in a PAM6m8 embodiment.

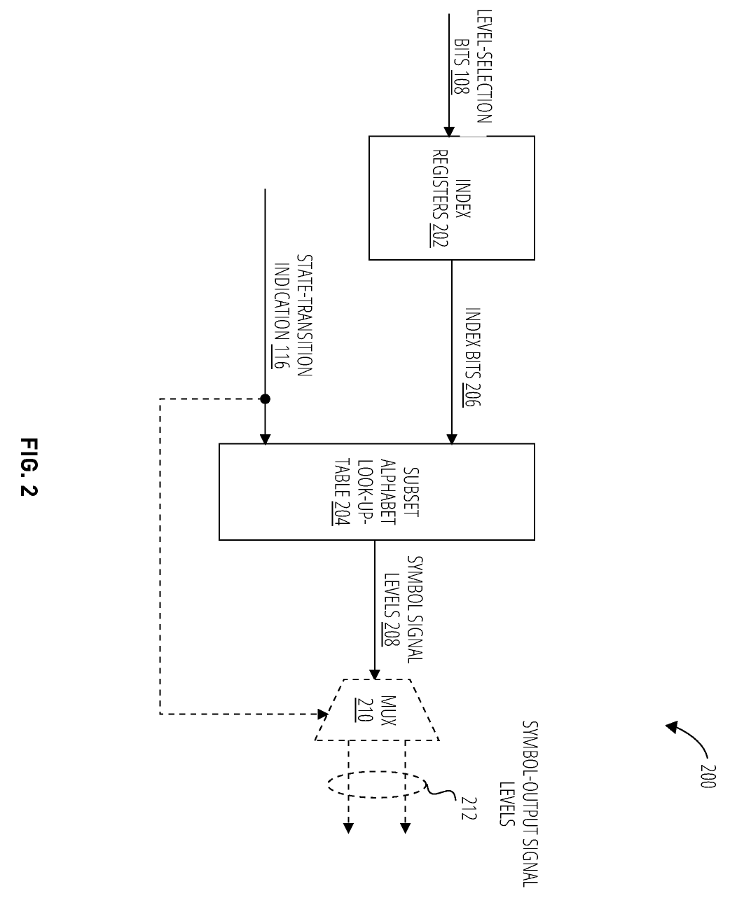

FIG. 2 is a block diagram depicting a detailed view of a mapper 200 for selecting symbol signal levels in a trellis-coded modulation system in accordance with one or more examples. The mapper 200 refines the symbol generation process implemented by mapper 102 of FIG. 1 by using indexed look-up to map bits to signal levels from designated subset-alphabets, supporting the emulation of lower-order modulations with constrained ordering.

The mapper 200 comprises index registers 202, subset alphabet look-up-table 204, and MUX 210.

The index registers 202 are storage elements that hold binary indices, generally used to address specific entries in tables or multiplexers. In one or more examples, the index registers 202 receive level-selection bits 108 and state-transition indication 116, generate index bits 206 based on a subset of input bits (e.g., 2 bits for selecting within a PAM4 subset), and provide these to the subset alphabet look-up-table 204 and MUX 210 to identify levels within a subset-alphabet, such as selecting between {7,3,-1,-5} in subset X using uncoded bits.

The subset alphabet look-up-table 204 is a memory-based table that associates identifiers with groups of signal levels, generally for efficient modulation mapping. In one or more examples, the subset alphabet look-up-table 204 stores partitioned subset-alphabets, receives the state-transition indication 116 to select a subset (e.g., A, B, C, or D from the less constrained partition, without limitation), and outputs symbol signal levels 208 that emulate lower-order schemes, ensuring pairwise disjoint subsets (e.g., no overlapping levels between A and B) and collective spanning of the constellation (e.g., all 8 PAM8 levels covered by X and Y, without limitation), with evaluations against thresholds like minimum spacing of 4 units for DC balance and power optimization.

The MUX 210 is a multiplexer that selects one of multiple inputs based on a control signal, generally for routing data paths. In one or more examples, the MUX 210 receives symbol signal levels 208 and index bits 206, selects the appropriate level (e.g., 7 or -1 from subset A using 1 bit, without limitation), and outputs symbol-output signal levels 212, which form the symbols for serialization, enabling precise mapping in various example variants such as where the first symbol is from PAM2 subsets and the second from PAM4 to constrain the decision feedback equalization tap, without limitation.

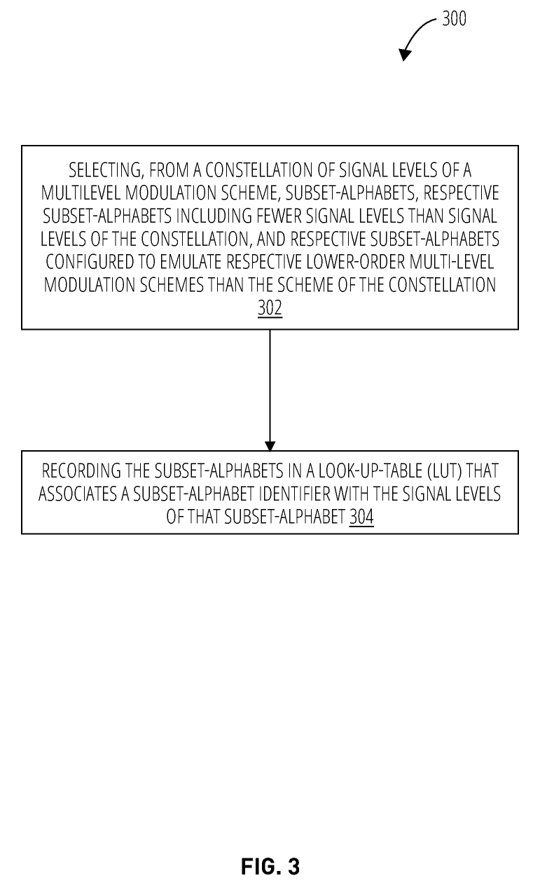

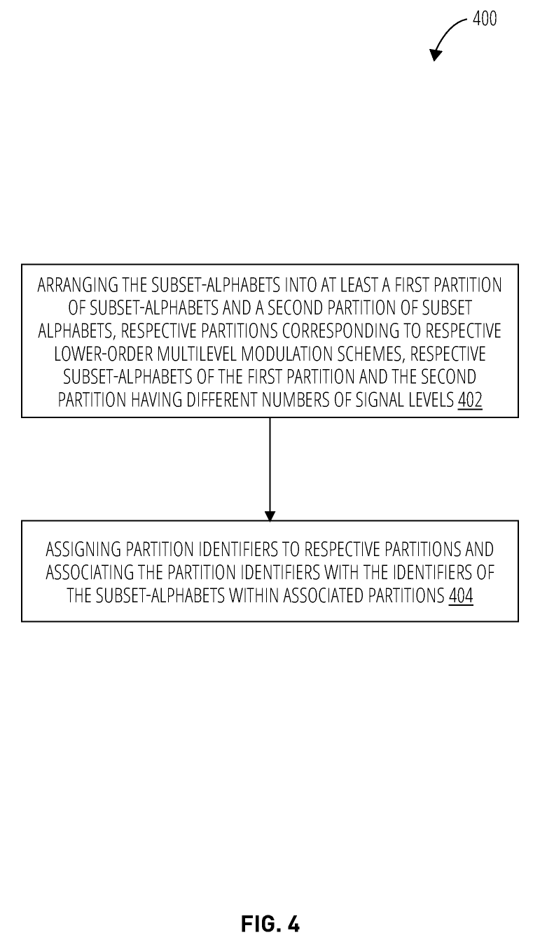

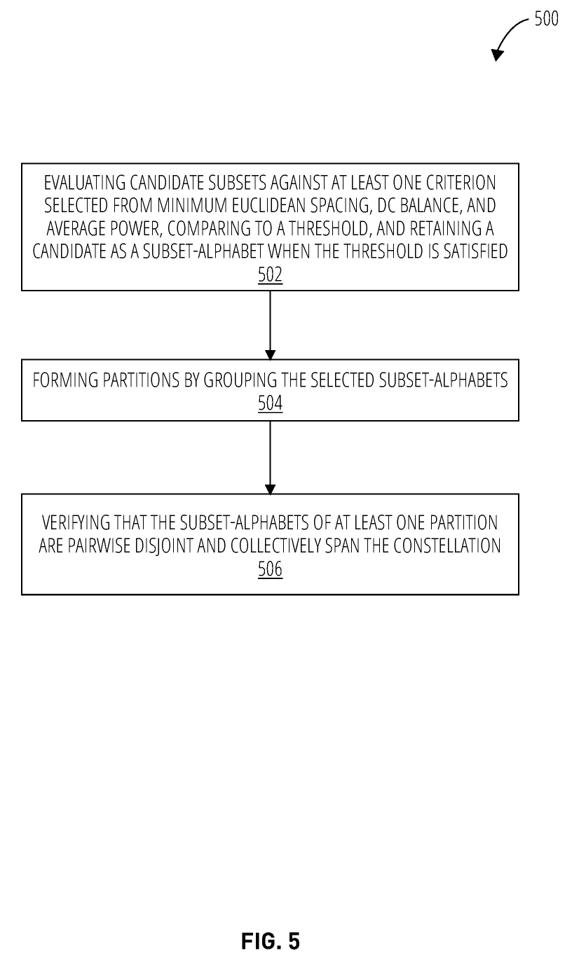

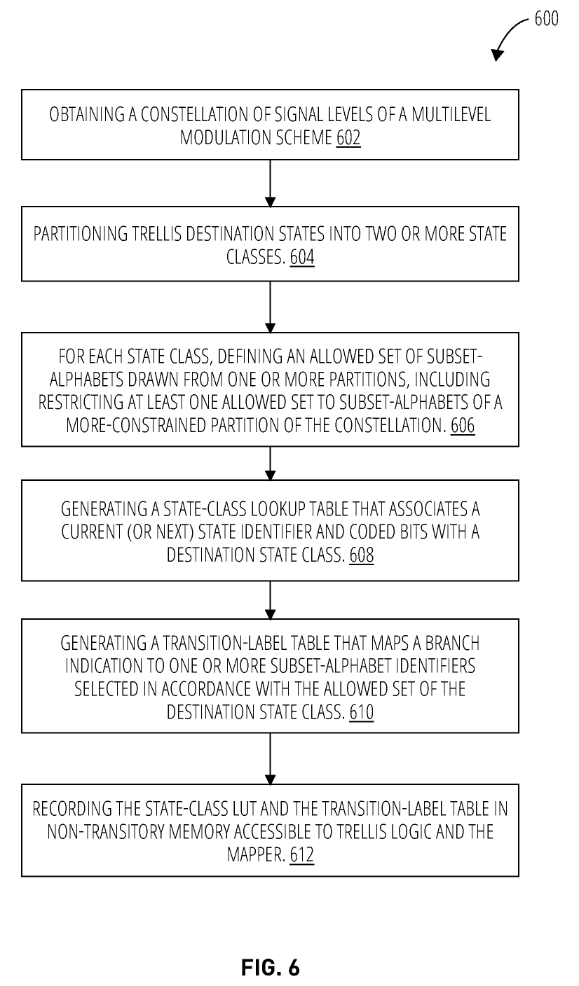

FIG. 3, FIG. 4, FIG. 5, and FIG. 6 depict methods for generating and configuring subset-alphabets and look-up tables (LUTs) used in trellis-coded modulation systems discussed herein, beginning in FIG. 3 with a general process for selecting and recording subsets from a high-order constellation (e.g., PAM8 levels) that emulate a lower-order scheme (e.g., PAM2 or PAM4), evaluated against criteria like Euclidean spacing, DC balance, and power. FIGS. 4 and 5 extend this by partitioning the subsets into at least two groups to enable creating multiple subset-alphabets for different emulated schemes (e.g., one group for PAM2 subsets and another for PAM4 subsets) that can be transmitted together in symbol groups, with verification of properties like disjointness and constellation spanning. FIG. 6 then associates these partitions with trellis state classes (groups of destination states that define allowed subset-alphabets for incoming transitions, e.g., even/odd classes restricting options based on state), generating LUTs for designation during encoding, which supports the overall system in producing ordered symbol groups via the serializer.

Although no specific block diagram is illustrated for the partitioning and configuration processes depicted in FIGS. 3-6, a person having ordinary skill in the art would understand that these processes may be implemented using logic circuitry, such as dedicated hardware modules, field-programmable gate arrays (FPGAs), application-specific integrated circuits (ASICs), or general-purpose processors executing software instructions stored in non-transitory memory, or combinations thereof, as would be understood by one of ordinary skill in the art to perform the selection, evaluation, partitioning, verification, and LUT generation steps in a trellis-coded modulation system.

FIG. 3 is a flow diagram depicting an example process 300 for configuring subset-alphabets in a trellis-coded modulation system, in accordance with one or more examples. Although the example process 300 depicts a particular sequence of operations, the sequence may be altered without departing from the scope of the present disclosure. For example, some of the operations depicted may be performed in parallel or in a different sequence that does not materially affect the function of the process 300. In other examples, different components of an example device or system that implements the process 300 may perform functions at substantially the same time or in a specific sequence.

According to one or more examples, process 300 may include selecting, from a constellation of signal levels of a multilevel modulation scheme, subset-alphabets, respective subset-alphabets including fewer signal levels than signal levels of the constellation, and respective subset-alphabets configured to emulate respective lower-order multi-level modulation schemes than the scheme of the constellation at operation 302. Generally, this operation partitions a high-order constellation into smaller groups for coding gain. In one or more examples, operation 302 evaluates candidate subsets from a PAM8 constellation {-7 to 7 in steps of 2}, retaining those with at least 2 levels (for PAM2 emulation) or 4 levels (for PAM4), configured to mimic PAM2 or PAM4 signaling. For instance, subset A{7,-1} emulates binary levels with large spacing (8 units) to reduce errors, while ensuring subsets meet criteria like minimum Euclidean distance (e.g., 4 units threshold) and are suitable for partitioning into less constrained (e.g., 4 PAM2 subsets, without limitation) and more constrained (e.g., 2 PAM4 subsets, without limitation) groups to limit last-symbol variability.

According to one or more examples, process 300 may include recording the subset-alphabets in a look-up-table (LUT) that associates a subset-alphabet identifier with the signal levels of that subset-alphabet at operation 304. Generally, this stores mappings for quick access. In one or more examples, operation 304 populates the LUT with identifiers (e.g., 'A' for {7,-1}, 'X' for {7,3,-1,-5}, without limitation), enabling trellis logic to designate them during transitions. This supports embodiments where subsets are partitioned for constraint, such as PAM2 subsets for the less constrained first partition (higher variability, smaller minimum spacing of 2 units) and PAM4 for the more constrained second partition (fewer options, larger spacing of 4 units), facilitating ordered symbol generation where the last symbol reduces DFE tap hypotheses from 8 to 4 levels in PAM8 systems.

Having described, in FIG. 3, an example process for configuring foundational subset-alphabets in a trellis-coded modulation system, FIG. 4 illustrates a process 400 for partitioning these subset-alphabets, organizing them into partitions to enable differential constraints for symbol ordering and improved receiver performance.

FIG. 4 is a flow diagram depicting an example process 400 for partitioning subset-alphabets in a trellis-coded modulation system, in accordance with one or more examples. Although the example process 400 depicts a particular sequence of operations, the sequence may be altered without departing from the scope of the present disclosure. For example, some of the operations depicted may be performed in parallel or in a different sequence that does not materially affect the function of the process 400. In other examples, different components of an example device or system that implements the process 400 may perform functions at substantially the same time or in a specific sequence.

According to one or more examples, process 400 may include arranging the subset-alphabets into at least a first partition of subset-alphabets and a second partition of subset-alphabets, respective partitions corresponding to respective lower-order multilevel modulation schemes, respective subset-alphabets of the first partition and the second partition having different numbers of signal levels at operation 402. Generally, this groups subsets by properties for modulation control. In one or more examples, operation 402 forms a first partition with 4 subsets (e.g., A/B/C/D, each with 2 levels for PAM2 emulation, smaller inter-level spacing of 2 units minimum leading to higher variability, without limitation) and a second with 2 subsets (e.g., X/Y, each with 4 levels for PAM4 emulation, larger spacing of at least 4 units to constrain options, without limitation), ensuring the second partition has fewer subsets to limit viable last-symbol levels (e.g., only X or Y, covering 4 levels each but disjointly spanning the constellation, without limitation).

According to one or more examples, process 400 may include assigning partition identifiers to respective partitions and associating the partition identifiers with the identifiers of the subset-alphabets within associated partitions at operation 404. Generally, this labels groups for reference. In one or more examples, operation 404 assigns 'P1' to the less constrained partition (e.g., PAM2 subsets with more options and potential for all 8 levels if unordered, without limitation) and 'P2' to the more constrained (e.g., PAM4 subsets, without limitation), linking to subset IDs for trellis designation. This enables 8-state TCM where transitions from even states use P1 first and P2 last, limiting last-symbol levels to 4 for better receiver performance, such as reduced path filtering errors in decoders by increasing slicer distances and minimizing confusions (e.g., between levels 5 and 7, without limitation).

Having described, in FIG. 4, an example process for partitioning subset-alphabets to support constrained symbol generation, FIG. 5 illustrates a process 500 for evaluating and forming these partitions, ensuring subsets meet performance criteria before grouping and verifying coverage properties.

FIG. 5 is a flow diagram depicting an example process 500 for evaluating and forming partitions of subset-alphabets in a trellis-coded modulation system, in accordance with one or more examples. Although the example process 500 depicts a particular sequence of operations, the sequence may be altered without departing from the scope of the present disclosure. For example, some of the operations depicted may be performed in parallel or in a different sequence that does not materially affect the function of the process 500. In other examples, different components of an example device or system that implements the process 500 may perform functions at substantially the same time or in a specific sequence.

According to one or more examples, process 500 may include evaluating candidate subsets against at least one criterion selected from minimum Euclidean spacing, DC balance, and average power, comparing to a threshold, and retaining a candidate as a subset-alphabet when the threshold is satisfied at operation 502. Generally, this filters subsets for transmission quality. In one or more examples, operation 502 checks spacing (e.g., threshold 4 units for constrained subsets to double distance from 2 units in less constrained ones, without limitation), DC balance (e.g., mean <0.1 to prevent baseline wander), and power (e.g., average <20 units squared for energy efficiency, without limitation), retaining e.g., subset X{7,3,-1,-5} which satisfies all for PAM4 emulation with levels spaced at least 4 units apart, enhancing noise immunity for last-symbol use.

According to one or more examples, process 500 may include forming partitions by grouping the selected subset-alphabets at operation 504. Generally, this organizes for use. In one or more examples, operation 504 groups into first (less constrained, more subsets like 4 PAM2 with 2 levels each) and second (more constrained, fewer subsets like 2 PAM4 with 4 levels each), as in PAM6m8 where PAM2 groups form the first partition (higher variability if used last) and PAM4 the second (restricted to reduce DFE tap options).

According to one or more examples, process 500 may include verifying that the subset-alphabets of at least one partition are pairwise disjoint and collectively span the constellation at operation 506. Generally, this ensures coverage without overlap. In one or more examples, operation 506 confirms for the second partition (e.g., X and Y disjoint with no shared levels, union equals full PAM8 {-7 to 7}, without limitation), preventing decoding ambiguity and ensuring all levels are usable. This is critical for maintaining coding rate in 16-state trellises, where duplicated states enforce restrictions, avoiding heterogeneous issues while supporting emulation of dual PAM2 symbols with constrained last-symbol levels limited to 4 options (e.g., A or C for certain classes, without limitation).

FIG. 6 is a flow diagram depicting an example process 600 for configuring trellis states and look-up tables in a trellis-coded modulation system, in accordance with one or more examples. Although the example process 600 depicts a particular sequence of operations, the sequence may be altered without departing from the scope of the present disclosure. For example, some of the operations depicted may be performed in parallel or in a different sequence that does not materially affect the function of the process 600. In other examples, different components of an example device or system that implements the process 600 may perform functions at substantially the same time or in a specific sequence.

According to one or more examples, process 600 may include obtaining a constellation of signal levels of a multilevel modulation scheme at operation 602. Generally, this loads the base levels. In one or more examples, operation 602 acquires PAM8 levels {-7,-5,-3,-1,1,3,5,7} for partitioning into subsets like A{7,-1} (PAM2 emulation) and X{7,3,-1,-5} (PAM4), providing the foundation for constraints where inter-level spacing in constrained partitions is at least twice that in less constrained ones.

According to one or more examples, process 600 may include partitioning trellis destination states into two or more state classes at operation 604. Generally, this classifies states for transition rules. In one or more examples, operation 604 divides into even (0-3) and odd (4-7) classes for 8-state TCM, or duplicated classes (e.g., 0A/0B for A/C vs. B/D restrictions, without limitation) in 16-state heterogeneous trellises, enabling enforcement of last-symbol constraints to limit entry levels and reduce decoder confusion.

According to one or more examples, process 600 may include, for each state class, defining an allowed set of subset-alphabets drawn from one or more partitions, including restricting at least one allowed set to subset-alphabets of a more-constrained partition of the constellation at operation 606. Generally, this limits options. In one or more examples, operation 606 restricts last-symbol subsets to the second partition (e.g., X for class 1 with levels {7,3,-1,-5}, Y for class 2 with {5,1,-3,-7}), ensuring larger spacing (e.g., 4 units minimum vs. 2 in first partition) for the DFE tap, thereby halving viable levels and increasing error margins (e.g., slicers at even intervals to avoid mistaking close levels like 3 and 5, without limitation).

According to one or more examples, process 600 may include generating a state-class lookup table that associates a current (or next) state identifier and coded bits with a destination state class at operation 608. Generally, this maps for quick lookup. In one or more examples, operation 608 creates a table where input bits and state ID yield class (e.g., bits 00-11 map state 0 to class 1 with X restriction, ensuring transitions label ordered pairs like A-X for even states).

According to one or more examples, process 600 may include generating a transition-label table that maps a branch indication to one or more subset-alphabet identifiers selected in accordance with the allowed set of the destination state class at operation 610. Generally, this labels branches. In one or more examples, operation 610 maps to ordered pairs (e.g., A-X, B-X for class 1 transitions), enforcing P1 (less constrained) first and P2 (more constrained) last, supporting 8 transition groups like AX, BX, CX, DX for even states to encode 3 bits per group while minimizing last-symbol options.

According to one or more examples, process 600 may include recording the state-class LUT and the transition-label table in non-transitory memory accessible to trellis logic and the mapper at operation 612. Generally, this stores for runtime. In one or more examples, operation 612 saves in memory (e.g., ROM or RAM, without limitation) for access, enabling efficient 3-bit encoding per group with reduced decoder errors in examples such as examples where heterogeneous states (e.g., some with 6 branches, without limitation) optimize hardware by enforcing restrictions at state entry.

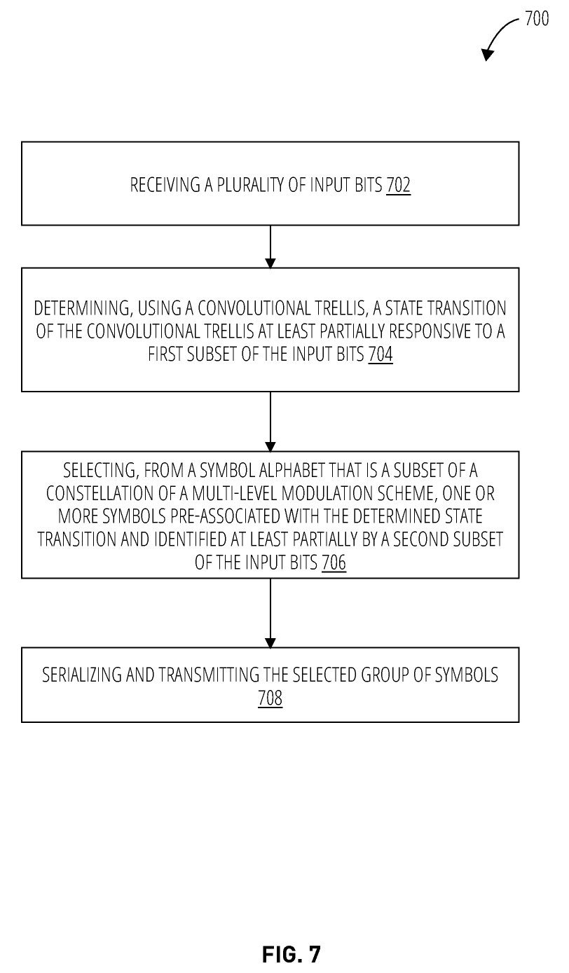

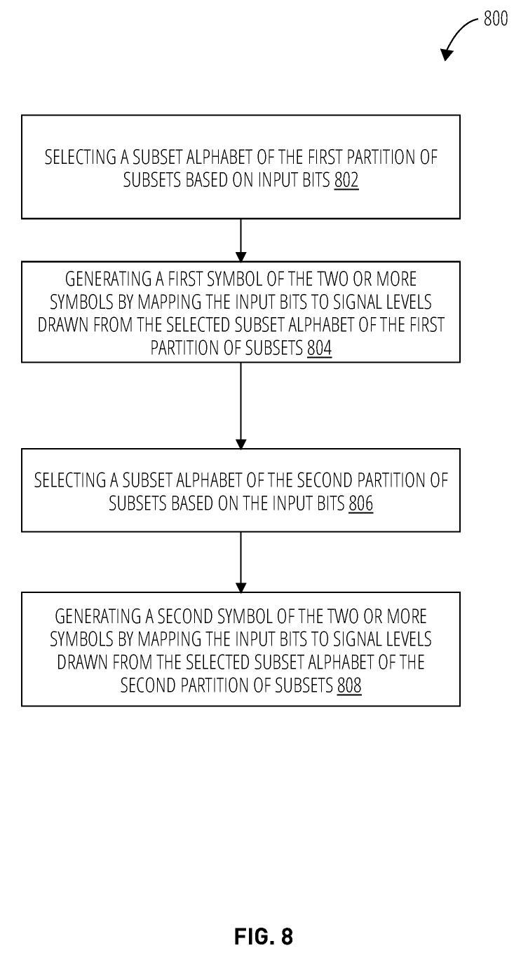

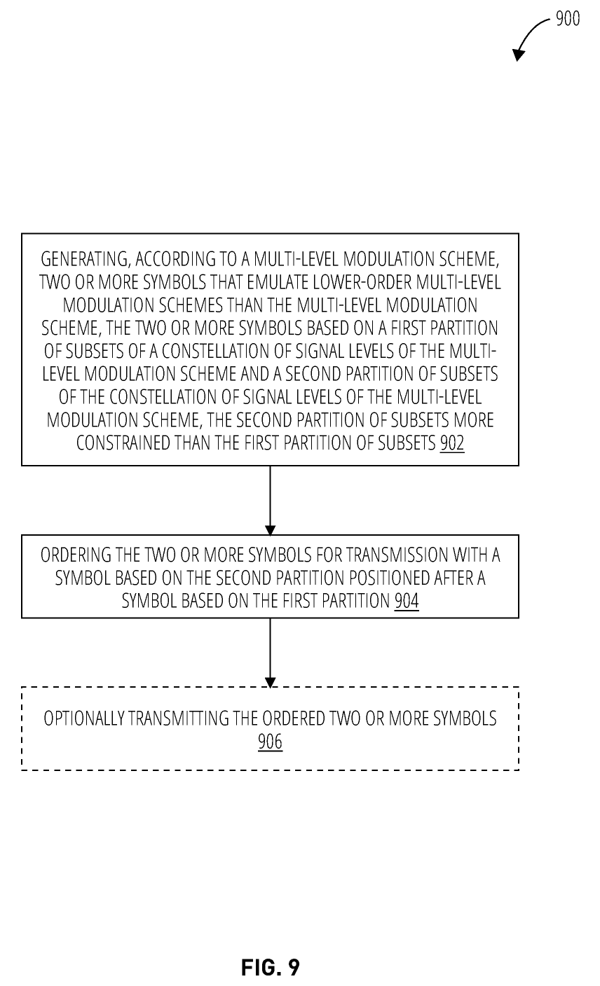

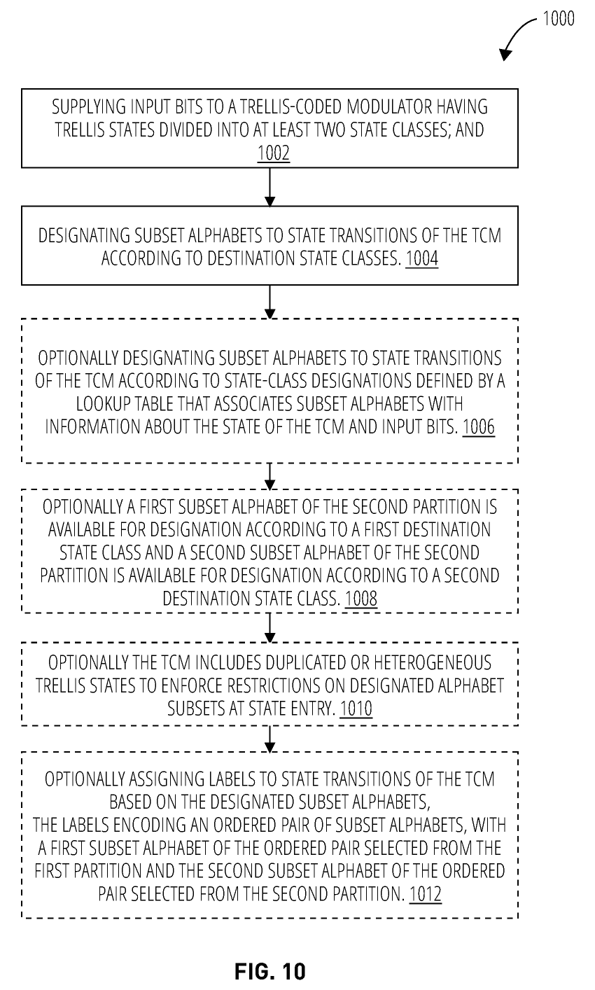

FIG. 7, FIG. 9, FIG. 8 and FIG. 10 depict processes for encoding and transmitting symbols in trellis-coded modulation systems discussed herein, beginning in FIG. 7 with a general process for receiving input bits, determining a trellis state transition, selecting a group of symbols from subsets of a high-order constellation (e.g., PAM8 levels) that emulate lower-order schemes (e.g., PAM2 or PAM4), and serializing/transmitting the group. FIGS. 8 and 9 extend this by generating two or more symbols from partitioned subsets for different emulated schemes (e.g., one from PAM2 subsets and another from PAM4 subsets) that are transmitted together in symbol groups, with detailed mapping of input bits to signal levels within selected subsets. FIG. 10 then designates these subset-alphabets to trellis transitions according to destination state classes (groups of states that restrict allowed subsets for incoming branches, e.g., even/odd classes specifying availability like X for one class and Y for another), which supports the overall system in ordering symbol groups via the serializer, positioning symbols from certain partitions last to increase performance.

FIG. 7 is a flow diagram depicting an example process 700 for encoding and transmitting symbols using a convolutional trellis in a trellis-coded modulation system, in accordance with one or more examples. Although the example process 700 depicts a particular sequence of operations, the sequence may be altered without departing from the scope of the present disclosure. For example, some of the operations depicted may be performed in parallel or in a different sequence that does not materially affect the function of the process 700. In other examples, different components of an example device or system that implements the process 700 may perform functions at substantially the same time or in a specific sequence. In one or more examples, some or a totality of operations of process 700 may be performed, as non-limiting examples, by TCM transmitter 100 or mapper 200.

According to one or more examples, process 700 may include receiving a plurality of input bits at operation 702. Generally, this inputs data. In one or more examples, operation 702 receives bits (e.g., 5 bits for 2 symbols in PAM6m8, with 3 coded for trellis selection and 2 uncoded for level mapping, without limitation), providing the raw data to be encoded into symbols emulating lower-order schemes.

According to one or more examples, process 700 may include determining, using a convolutional trellis, a state transition of the convolutional trellis at least partially responsive to a first subset of the input bits at operation 704. Generally, this computes paths. In one or more examples, operation 704 uses coded bits (e.g., 3 bits in 8-state TCM, without limitation) to select a transition that designates a subset-alphabet (e.g., labeling a subset from which symbols are drawn), associating the transition with pre-defined subsets of the constellation to enable emulation of lower-order modulation.

According to one or more examples, process 700 may include selecting, from a symbol alphabet that is a subset of a constellation of a multi-level modulation scheme, one or more symbols pre-associated with the determined state transition and identified at least partially by a second subset of the input bits at operation 706. Generally, this maps to symbols. In one or more examples, operation 706 uses uncoded bits (e.g., 2 bits) to pick levels within the subset (e.g., selecting from levels like {7,3,-1,-5} to form symbols), emulating a lower-order scheme (e.g., PAM4 within PAM8, without limitation) while optionally ensuring the symbols span the constellation of the higher-order scheme.

According to one or more examples, process 700 may include serializing and transmitting the selected group of symbols at operation 708. Generally, this orders and sends. In one or more examples, operation 708 serializes the symbols for transmission, supporting ordered output to increase performance in high-speed channels with decision feedback equalization.

FIG. 8 is a flow diagram depicting an example process 800 for detailed symbol generation from partitions in a trellis-coded modulation system, in accordance with one or more examples. Although the example process 800 depicts a particular sequence of operations, the sequence may be altered without departing from the scope of the present disclosure. For example, some of the operations depicted may be performed in parallel or in a different sequence that does not materially affect the function of the process 800. In other examples, different components of an example device or system that implements the process 800 may perform functions at substantially the same time or in a specific sequence. In one or more examples, some or a totality of operations of process 800 may be performed, as non-limiting examples, by TCM transmitter 100 or mapper 200.

According to one or more examples, process 800 may include selecting a subset alphabet of the first partition of subsets based on input bits at operation 802. Generally, this chooses a group. In one or more examples, operation 902 uses coded bits (e.g., from trellis transition, without limitation) to pick e.g., A{7,-1} from first less constrained partition (PAM2, 4 options).

According to one or more examples, process 800 may include generating a first symbol of the two or more symbols by mapping the input bits to signal levels drawn from the selected subset alphabet of the first partition of subsets at operation 804. Generally, this maps. In one or more examples, operation 904 uses uncoded bits (e.g., 1 bit, without limitation) to select e.g., 7 or -1 from A, emulating PAM2 with smaller spacing but positioned first to avoid DFE impact.

According to one or more examples, process 800 may include selecting a subset alphabet of the second partition of subsets based on the input bits at operation 806. Generally, this chooses. In one or more examples, operation 906 picks e.g., X{7,3,-1,-5} from second more constrained partition (PAM4, 2 options), restricted by state class.

According to one or more examples, process 800 may include generating a second symbol of the two or more symbols by mapping the input bits to signal levels drawn from the selected subset alphabet of the second partition of subsets at operation 808. Generally, this maps. In one or more examples, operation 808 selects e.g., 3 or -5 from X using uncoded bits, ensuring larger spacing (4 units) for the last symbol to limit DFE tap variability and decoder errors.

FIG. 9 is a flow diagram depicting an example process 900 for generating and ordering symbols in a multi-level modulation scheme, in accordance with one or more examples. Although the example process 900 depicts a particular sequence of operations, the sequence may be altered without departing from the scope of the present disclosure. For example, some of the operations depicted may be performed in parallel or in a different sequence that does not materially affect the function of the process 900. In other examples, different components of an example device or system that implements the process 900 may perform functions at substantially the same time or in a specific sequence. In one or more examples, some or a totality of operations of process 900 may be performed, as non-limiting examples, by TCM transmitter 100 or mapper 200.

According to one or more examples, process 800 may include generating, according to a multi-level modulation scheme, two or more symbols that emulate lower-order multi-level modulation schemes than the multi-level modulation scheme, the two or more symbols based on a first partition of subsets of a constellation of signal levels of the multi-level modulation scheme and a second partition of subsets of the constellation of signal levels of the multi-level modulation scheme, the second partition of subsets more constrained than the first partition of subsets at operation 802. Generally, this creates symbols. In one or more examples, operation 802 generates e.g., one PAM2 symbol from first partition (4 subsets, 2 levels each, spacing 2 units min. for higher variability) and one PAM4 from second (2 subsets, 4 levels each, spacing ≥4 units), using trellis transitions to designate subsets and map bits to levels.

According to one or more examples, process 800 may include ordering the two or more symbols for transmission with a symbol based on the second partition positioned after a symbol based on the first partition at operation 804. Generally, this sequences. In one or more examples, operation 804 positions PAM4 last to limit levels (e.g., 4 options from X or Y) for DFE tap, reducing hypotheses in decoders and increasing minimum distances (e.g., to 4 units) to prevent errors like level confusions.

According to one or more examples, process 800 may include optionally transmitting the ordered two or more symbols at operation 806. Generally, this sends. In one or more examples, operation 806 transmits the ordered symbols, improving receiver path filtering and overall system performance in noisy channels by constraining the last symbol's variability.

FIG. 10 is a flow diagram depicting an example process 1000 for designating subsets in a trellis-coded modulator, in accordance with one or more examples. Although the example process 1000 depicts a particular sequence of operations, the sequence may be altered without departing from the scope of the present disclosure. For example, some of the operations depicted may be performed in parallel or in a different sequence that does not materially affect the function of the process 1000. In other examples, different components of an example device or system that implements the process 1000 may perform functions at substantially the same time or in a specific sequence. In one or more examples, some or a totality of operations of process 1000 may be performed, as non-limiting examples, by TCM transmitter 100 or mapper 200.

According to one or more examples, process 1000 may include supplying input bits to a trellis-coded modulator having trellis states divided into at least two state classes at operation 1002. Generally, this inputs to TCM. In one or more examples, operation 1002 provides bits (e.g., 3 coded bits for 8-state) to a TCM with classes (e.g., even/odd or duplicated Jekyll/Hyde for heterogeneous enforcement), setting the stage for constrained designation.

According to one or more examples, process 1000 may include designating subset alphabets to state transitions of the TCM according to destination state classes at operation 1004. Generally, this assigns. In one or more examples, operation 1004 designates ordered pairs (e.g., P1-P2 like A-X) based on class, restricting last to more constrained partition (e.g., X for class 1), limiting entry levels to 4 and doubling minimum distances for better slicer performance.

According to one or more examples, process 1000 may include, optionally, designating subset alphabets to state transitions of the TCM according to state-class designations defined by a lookup table (LUT) that associates subset alphabets with information about the state of the TCM and input bits, at operation 1006.

According to one or more examples, process 1000 may include, optionally, a first subset alphabet of the second partition being available for designation according to a first destination state class and a second subset alphabet of the second partition being available for designation according to a second destination state class at operation 1008. Generally, this specifies availability. In one or more examples, operation 1008 makes X available for class 1 (states 0-3, levels {7,3,-1,-5}) and Y for class 2 (4-7, {5,1,-3,-7}), ensuring disjoint constrained options that span the constellation while reducing DFE variability.

According to some examples, process 1000 may include, optionally, the TCM including duplicated or heterogenous trellis states to enforce restrictions on designated alphabet subsets at state entry, at operation 1010.

According to some examples, process 1000 may include, optionally, assigning labels to state transitions of the TCM based on the designated subset alphabets, the labels encoding an ordered pair of subset alphabets, with a first alphabet of the ordered pair being selected from the first partition and the second subset alphabet of the ordered pair being selected from the second partition, at operation 1012.

According to some examples, process 1000 may include, optionally, assigning labels to state transitions of the TCM based on the designated subset alphabets. This organizes transitions for encoding. In one or more examples, this optional operation encodes ordered pairs of subset alphabets (e.g., first from less constrained partition, second from more constrained), with labels like AX, BX for even states, enabling 8 different transition groups to encode 3 bits while enforcing restrictions at state entry, as in duplicated states for 16-state trellises to handle dual PAM2 emulation without full variability in the last symbol.

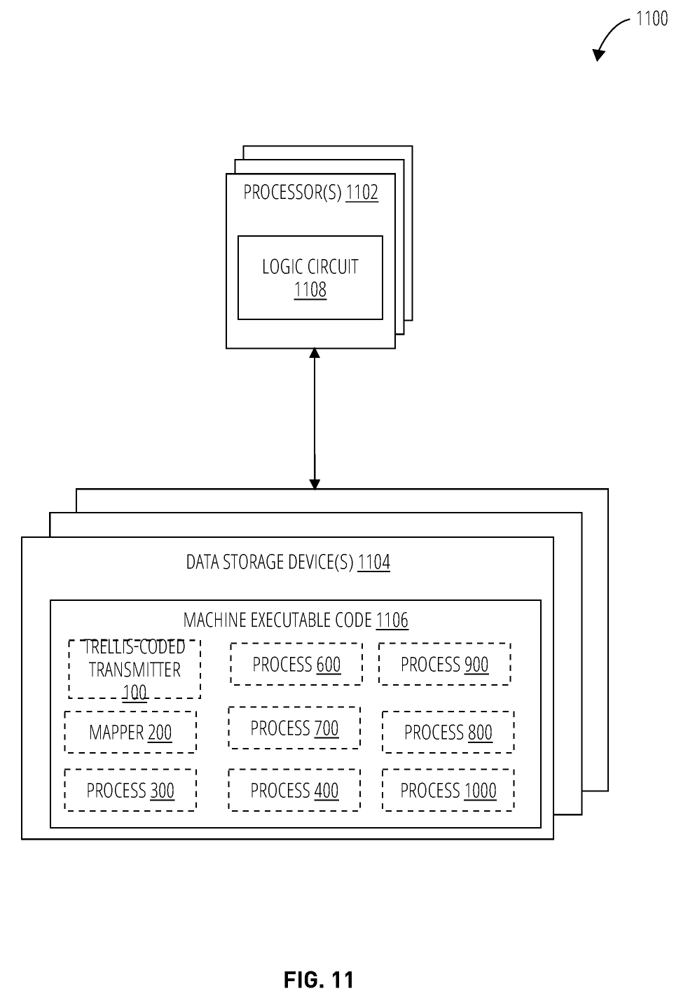

It will be appreciated by those of ordinary skill in the art that functional elements of examples disclosed herein (e.g., functions, operations, acts, processes, or methods) may be implemented in any suitable hardware, software, firmware, or combinations thereof. FIG. 11 illustrates non-limiting examples of implementations of functional elements disclosed herein. In some examples, some or all portions of the functional elements disclosed herein may be performed by hardware capable of carrying out the functional elements.

FIG. 11 is a block diagram of a circuitry 1100 that, in some examples, may be used to implement various functions, operations, acts, processes, or methods disclosed herein. The circuitry 1100 includes one or more processors 1102 (sometimes referred to herein as “processors 1102”) operably coupled to one or more data storage devices 1104 (sometimes referred to herein as “storage 1104”). The storage 1104 includes machine executable code 1106 stored thereon and the processors 1102 include logic circuit 1108. The machine executable code 1106 includes information describing functional elements that may be implemented by (e.g., performed by) the logic circuit 1108. The logic circuit 1108 is adapted to implement (e.g., perform) the functional elements described by the machine executable code 1106. The circuitry 1100, when executing the functional elements described by the machine executable code 1106, should be considered as special purpose hardware for carrying out functional elements disclosed herein. In one or more examples, the processors 1102 may perform the functional elements described by the machine executable code 1106 sequentially, concurrently (e.g., on one or more different hardware platforms), or in one or more parallel process streams.

When implemented by logic circuit 1108 of the processors 1102, the machine executable code 1106 adapts the processors 1102 to perform operations of examples disclosed herein. By way of non-limiting example, the machine executable code 1106 may adapt the processors 1102 to perform some or a totality of operations of one or more of: process 300, process 400, process 500, process 600, process 700, process 800, or process 900.

Also by way of non-limiting example, the machine executable code 1106 may adapt the processors 1102 to perform some or a totality of features, functions, or operations disclosed herein for one or more of: trellis-coded transmitter 100 including mapper 102, convolutional trellis logic or 104; and 200 including index registers 202, subset alphabet look-up-table 204, or mux 210.

The processors 1102 may include a general purpose processor, a special purpose processor, a central processing unit (CPU), a microcontroller, a programmable logic controller (PLC), a digital signal processor (DSP), an application specific integrated circuit (ASIC), a field-programmable gate array (FPGA) or other programmable logic device (PLD), discrete gate or transistor logic, discrete hardware components, other programmable device, or any combination thereof designed to perform the functions disclosed herein. A general-purpose computer including one or more processors 1102, including a general-purpose processor, is considered a special-purpose computer at least while the general-purpose computer executes functional elements corresponding to the machine executable code 1106 (e.g., software code, firmware code, configuration data, hardware descriptions, without limitation) related to examples of the present disclosure. It is noted that a general-purpose processor (which may also be referred to herein as a host processor or simply a host) may be a microprocessor, but in the alternative, a general-purpose processor of processors 1102 may include any conventional processor, controller, microcontroller, or state-machine. An FPGA or other PLD of the processors 1102 may be configured (e.g., programmed, without limitation) with configuration data to perform functions disclosed herein, or, additionally or alternatively, may be capable of being configured or re-configured (e.g., programmable or re-programmable, without limitation) with configuration data to perform functions disclosed herein. The processors 1102 may also be implemented as a combination of computing devices, such as a combination of a DSP and a microprocessor, a plurality of microprocessors, one or more microprocessors in conjunction with a DSP core, or any other such configuration.

In one or more examples, the storage 1104 includes volatile data storage (e.g., random-access memory (RAM), static RAM (SRAM), without limitation), non-volatile data storage (e.g., Flash memory, a hard disc drive, a solid state drive, erasable programmable read-only memory (EPROM), without limitation). In some examples the processors 1102 and the storage 1104 may be implemented into a single device (e.g., a semiconductor device product, a system on chip (SOC), without limitation). In some examples the processors 1102 and the storage 1104 may be implemented into separate devices.

In one or more examples the machine executable code 1106 may include computer-readable instructions (e.g., software code, firmware code). By way of non-limiting example, the computer-readable instructions may be stored by the storage 1104, accessed directly by the processors 1102, and executed by the processors 1102 using at least the logic circuit 1108. Also by way of non-limiting example, the computer-readable instructions may be stored on the storage 1104, transferred to a memory device (not shown) for execution, and executed by the processors 1102 using at least the logic circuit 1108. Processors 1102 or logic circuit 1108 thereof be coupled to such a memory device or include such a memory device (e.g., a configuration memory cell, without limitation). Accordingly, in some examples the logic circuit 1108 includes electrically configurable logic circuit 1108.

In one or more examples the machine executable code 1106 may describe hardware (e.g., circuitry) to be implemented in the logic circuit 1108 to perform the functional elements. This hardware may be described at any of a variety of levels of abstraction, from low-level transistor layouts to high-level description languages. At a high-level of abstraction, a hardware description language (HDL) such as an IEEE Standard hardware description language (HDL) may be used. By way of non-limiting examples, VERILOG®, SystemVerilog® or very-large scale integration (VLSI) hardware description language (VHDL) may be used.

HDL descriptions may be converted into descriptions at any of numerous other levels of abstraction as desired. As a non-limiting example, a high-level description can be converted to a logic-level description such as a register-transfer language (RTL), a gate-level (GL) description, a layout-level description, or a mask-level description. As a non-limiting example, micro-operations to be performed by hardware logic circuits (e.g., gates, flip-flops, registers, without limitation) of the logic circuit 1108 may be described in a RTL and then converted by a synthesis tool into a GL description, and the GL description may be converted by a placement and routing tool into a layout-level description that corresponds to a physical layout of an integrated circuit of a programmable logic device, discrete gate or transistor logic, discrete hardware components, or combinations thereof. Accordingly, in some examples the machine executable code 1106 may include an HDL, an RTL, a GL description, a mask level description, other hardware description, or any combination thereof.

In examples where the machine executable code 1106 includes a hardware description (at any level of abstraction), a system (not shown, but including the storage 1104) implements the hardware description described by the machine executable code 1106. By way of non-limiting example, the processors 1102 may include a programmable logic device (e.g., an FPGA or a PLC, without limitation) and the logic circuit 1108 may be electrically controlled (e.g., via configuration data, without limitation) to implement circuitry corresponding to the hardware description into the logic circuit 1108. Also, by way of non-limiting example, the logic circuit 1108 may include hard-wired logic manufactured by a manufacturing system (not shown, but including the storage 1104) according to the hardware description of the machine executable code 1106.

Regardless of whether the machine executable code 1106 includes computer-readable instructions or a hardware description, the logic circuit 1108 is adapted to perform the functional elements described by the machine executable code 1106 when implementing the functional elements of the machine executable code 1106. It is noted that although a hardware description may not directly describe functional elements, a hardware description indirectly describes functional elements that the hardware elements described by the hardware description are capable of performing.

As used in the present disclosure, the terms “module” or “component” may refer to specific hardware implementations to perform the actions of the module or component and/or software objects or software routines that may be stored on and/or executed by general purpose hardware (e.g., computer-readable media, processing devices, without limitation) of the computing system. In some examples, the different components, modules, engines, and services described in the present disclosure may be implemented as objects or processes that execute on the computing system (e.g., as separate threads). While some of the systems and methods described in the present disclosure are generally described as being implemented in software (stored on and/or executed by general purpose hardware), specific hardware implementations or a combination of software and specific hardware implementations are also possible and contemplated.

As used in the present disclosure, the term “combination” with reference to a plurality of elements may include a combination of all the elements or any of various different subcombinations of some of the elements. For example, the phrase “A, B, C, D, or combinations thereof” may refer to any one of A, B, C, or D; the combination of each of A, B, C, and D; and any subcombination of A, B, C, or D such as A, B, and C; A, B, and D; A, C, and D; B, C, and D; A and B; A and C; A and D; B and C; B and D; or C and D.

Terms used in the present disclosure and especially in the appended claims (e.g., bodies of the appended claims, without limitation) are generally intended as “open” terms (e.g., the term “including” should be interpreted as “including, but not limited to,” the term “having” should be interpreted as “having at least,” the term “includes” should be interpreted as “includes, but is not limited to,” without limitation). As used herein, the term “each” means “some or a totality.” As used herein, the term “each and every” means a “totality.”

Additionally, if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (e.g., “a” and/or “an” should be interpreted to mean “at least one” or “one or more,” without limitation); the same holds true for the use of definite articles used to introduce claim recitations.

In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations, without limitation). Furthermore, in those instances where a convention analogous to “at least one of A, B, and C, without limitation” or “one or more of A, B, and C, without limitation” is used, in general such a construction is intended to include A alone, B alone, C alone, A and B together, A and C together, B and C together, or A, B, and C together, without limitation.

Further, any disjunctive word or phrase presenting two or more alternative terms, whether in the description, claims, or drawings, should be understood to contemplate the possibilities of including one of the terms, either of the terms, or both terms. For example, the phrase “A or B” should be understood to include the possibilities of “A” or “B” or “A and B.”

### Additional non-limiting examples include:

Example 1: A method, comprising: receiving a plurality of input bits; determining, using a convolutional trellis, a state transition of the convolutional trellis at least partially responsive to a first subset of the input bits; selecting, from a symbol alphabet that is a subset of a constellation of signal‑level patterns of a multi-level modulation scheme, a group of symbols pre‑associated with the determined state transition and identified at least partially by a second subset of the input bits; and serializing and transmitting the selected group of symbols.

Example 2: The method according to Example 1, comprising: generating, according to the multi-level modulation scheme, two or more symbols that emulate lower-order multi-level modulation schemes than the multi-level modulation scheme, the two or more symbols based on a first partition of subsets of a constellation of signal levels of the multi-level modulation scheme and a second partition of subsets of the constellation of signal levels of the multi-level modulation scheme, the second partition of subsets more constrained than the first partition of subsets; and ordering the two or more symbols for transmission with a symbol based on the second partition positioned after a symbol based on the first partition.

Example 3: The method according to any of Examples 1 and 2, wherein the generating the two or more symbols comprises: selecting a subset alphabet of the first partition of subsets based on input bits; generating a first symbol of the two or more symbols by mapping the input bits to signal levels drawn from the selected subset alphabet of the first partition of subsets; selecting a subset alphabet of the second partition of subsets based on the input bits; and generating a second symbol of the two or more symbols by mapping the input bits to signal levels drawn from the selected subset alphabet of the second partition of subsets.

Example 4: The method according to any of Examples 1 through 3, wherein generating the two or more symbols comprises: supplying multiple input bits to a trellis‑coded modulator in which a group of bits of the multiple input bits select a trellis transition that designates a subset alphabet of the first partition and a subset alphabet of the second partition, and a group of remaining bits of the multiple input bits select signal levels within the designated subset alphabets.

Example 5: The method according to any of Examples 1 through 4, wherein the generating the two or more symbols comprises: supplying input bits to a trellis-coded modulator (TCM) having trellis states divided into at least two state classes; and designating subset alphabets to state transitions of the TCM according to destination state classes.

Example 6: The method according to any of Examples 1 through 5, wherein a first subset alphabet of the second partition is available for designation according to a first destination state class and a second subset alphabet of the second partition is available for designation according to a second destination state class.

Example 7: The method according to any of Examples 1 through 6, wherein the same subset alphabets of the first partition are available for designation according to the first destination state class and to the second destination state class.

Example 8: The method according to any of Examples 1 through 7, comprising: assigning labels to state transitions of the TCM based on the designated subset alphabets, wherein the labels encode an ordered pair of subset alphabets, with a first subset alphabet of the ordered pair selected from the first partition and the second subset alphabet of the ordered pair selected from the second partition.

Example 9: The method according to any of Examples 1 through 8, wherein designating subset alphabets to state transitions of the TCM according to destination state classes comprises: designating subset alphabets to state transitions of the TCM according to state-class designations defined by a lookup table that associates subset alphabets with information about the state of the TCM and input bits.

Example 10: The method according to any of Examples 1 through 9, wherein the TCM includes duplicated or heterogeneous trellis states to enforce restrictions on designated alphabet subsets at state entry.

Example 11: The method according to any of Examples 1 through 10, wherein an inter‑level spacing within subset alphabets of the second partition is at least twice an inter‑level spacing within subset alphabets of the first partition.

Example 12: The method according to any of Examples 1 through 11, wherein the first partition of subsets includes more subsets than the second partition of subsets.

Example 13: The method according to any of Examples 1 through 12, wherein subsets of the first partition collectively span a range of signal levels of the constellation of the multi-level modulation scheme, and subsets of the second partition collectively span the range of signal levels of the constellation of the multi-level modulation scheme.

Example 14: The method according to any of Examples 1 through 13, comprising: providing respective ones of the two or more symbols at respective ones of symbol outputs of a TCM encoder, including: a first symbol output pre-assigned to carry symbols drawn from the first partition, and a second symbol output pre-assigned to carry symbols drawn from the second partition.

Example 15: The method according to any of Examples 1 through 14, wherein the ordering the two or more symbols for transmission comprising: serializing the symbol outputs with a symbol from the first symbol output transmitted before a symbol from the second symbol output.

Example 16: The method according to any of Examples 1 through 15, comprising: tagging respective ones of the two or more symbols with respective position indexes; and buffering the two or more symbols according to an order specified by their respective position indexes; and serializing the buffered two or more symbols according to the order.

Example 17: An apparatus, comprising: a convolutional encoder and symbol mapper to: receive a plurality of input bits; determine, using a convolutional trellis, a state transition of the convolutional trellis at least partially responsive to a first subset of the input bits; and select, from a symbol alphabet that is a subset of a constellation of a multi-level modulation scheme, a group of symbols pre‑associated with the determined state transition and identified at least partially by a second subset of the input bits; and a serializer to serialize and transmit the selected group of symbols.

Example 18: The apparatus according to Example 17, wherein the convolutional encoder and symbol mapper to: generate, according to the multi-level modulation scheme, two or more symbols that emulate lower-order modulation schemes than the multi-level modulation scheme, the two or more ordered symbols based on a first partition of subsets of a constellation of signal levels of the multi-level modulation scheme and a second partition of subsets of the constellation of signal levels of the multi-level modulation scheme, the second partition of subsets more constrained than the first partition of subsets.

Example 19: The apparatus according to any of Examples 17 and 18, wherein the serializer to order the two or more symbols for transmission with a symbol based on the second partition positioned after a symbol based on the first partition.

While the present disclosure has been described herein with respect to certain illustrated examples, those of ordinary skill in the art will recognize and appreciate that the present invention is not so limited. Rather, many additions, deletions, and modifications to the illustrated and described examples may be made without departing from the scope of the invention as hereinafter claimed along with their legal equivalents. In addition, features from one example may be combined with features of another example while still being encompassed within the scope of the invention as contemplated by the inventor.

What is claimed is:

1. A method, comprising:
receiving a plurality of input bits;
determining, using a convolutional trellis, a state transition of the convolutional trellis at least partially responsive to a first subset of the input bits;
selecting, from a symbol alphabet that is a subset of a constellation of signal‑level patterns of a multi-level modulation scheme, a group of symbols pre‑associated with the determined state transition and identified at least partially by a second subset of the input bits; and
serializing and transmitting the selected group of symbols.

2. The method of claim 1, comprising:
generating, according to the multi-level modulation scheme, two or more symbols that emulate lower-order multi-level modulation schemes than the multi-level modulation scheme, the two or more symbols based on a first partition of subsets of a constellation of signal levels of the multi-level modulation scheme and a second partition of subsets of the constellation of signal levels of the multi-level modulation scheme, the second partition of subsets more constrained than the first partition of subsets; and
ordering the two or more symbols for transmission with a symbol based on the second partition positioned after a symbol based on the first partition.

3. The method of claim 2, wherein the generating the two or more symbols comprises:
selecting a subset alphabet of the first partition of subsets based on input bits;
generating a first symbol of the two or more symbols by mapping the input bits to signal levels drawn from the selected subset alphabet of the first partition of subsets;
selecting a subset alphabet of the second partition of subsets based on the input bits; and
generating a second symbol of the two or more symbols by mapping the input bits to signal levels drawn from the selected subset alphabet of the second partition of subsets.

4. The method of claim 3, wherein generating the two or more symbols comprises:
supplying multiple input bits to a trellis‑coded modulator in which a group of bits of the multiple input bits select a trellis transition that designates a subset alphabet of the first partition and a subset alphabet of the second partition, and a group of remaining bits of the multiple input bits select signal levels within the designated subset alphabets.

5. The method of claim 2, wherein the generating the two or more symbols comprises:
supplying input bits to a trellis-coded modulator (TCM) having trellis states divided into at least two state classes; and
designating subset alphabets to state transitions of the TCM according to destination state classes.

6. The method of claim 5, wherein a first subset alphabet of the second partition is available for designation according to a first destination state class and a second subset alphabet of the second partition is available for designation according to a second destination state class.

7. The method of claim 6, wherein the same subset alphabets of the first partition are available for designation according to the first destination state class and to the second destination state class.

8. The method of claim 5, comprising:
assigning labels to state transitions of the TCM based on the designated subset alphabets,
wherein the labels encode an ordered pair of subset alphabets, with a first subset alphabet of the ordered pair selected from the first partition and the second subset alphabet of the ordered pair selected from the second partition.

9. The method of claim 5, wherein designating subset alphabets to state transitions of the TCM according to destination state classes comprises:
designating subset alphabets to state transitions of the TCM according to state-class designations defined by a lookup table that associates subset alphabets with information about the state of the TCM and input bits.

10. The method of claim 5, wherein the TCM includes duplicated or heterogeneous trellis states to enforce restrictions on designated alphabet subsets at state entry.

11. The method of claim 2, wherein an inter‑level spacing within subset alphabets of the second partition is at least twice an inter‑level spacing within subset alphabets of the first partition.

12. The method of claim 2, wherein the first partition of subsets includes more subsets than the second partition of subsets.

13. The method of claim 2, wherein subsets of the first partition collectively span a range of signal levels of the constellation of the multi-level modulation scheme, and subsets of the second partition collectively span the range of signal levels of the constellation of the multi-level modulation scheme.

14. The method of claim 2, comprising:
providing respective ones of the two or more symbols at respective ones of symbol outputs of a TCM encoder, including: a first symbol output pre-assigned to carry symbols drawn from the first partition, and a second symbol output pre-assigned to carry symbols drawn from the second partition.

15. The method of claim 14, wherein the ordering the two or more symbols for transmission comprising:
serializing the symbol outputs with a symbol from the first symbol output transmitted before a symbol from the second symbol output.

16. The method of claim 2, comprising:
tagging respective ones of the two or more symbols with respective position indexes; and
buffering the two or more symbols according to an order specified by their respective position indexes; and
serializing the buffered two or more symbols according to the order.

17. An apparatus, comprising:
a convolutional encoder and symbol mapper to:
receive a plurality of input bits;
determine, using a convolutional trellis, a state transition of the convolutional trellis at least partially responsive to a first subset of the input bits; and
select, from a symbol alphabet that is a subset of a constellation of a multi-level modulation scheme, a group of symbols pre‑associated with the determined state transition and identified at least partially by a second subset of the input bits; and
a serializer to serialize and transmit the selected group of symbols.

18. The apparatus of claim 17, wherein the convolutional encoder and symbol mapper to:
generate, according to the multi-level modulation scheme, two or more symbols that emulate lower-order modulation schemes than the multi-level modulation scheme, the two or more ordered symbols based on a first partition of subsets of a constellation of signal levels of the multi-level modulation scheme and a second partition of subsets of the constellation of signal levels of the multi-level modulation scheme, the second partition of subsets more constrained than the first partition of subsets.

19. The apparatus of claim 18, wherein the serializer to order the two or more symbols for transmission with a symbol based on the second partition positioned after a symbol based on the first partition.
